(19) United States
(12) Patent Application Publication
(10) Pub. No.: US 2016/0143147 A1
(43) Pub. Date: May 19, 2016

(54) ELECTRONIC DEVICE MODULE AND METHOD OF MANUFACTURING THE SAME

(71) Applicant: Samsung Electro-Mechanics Co., Ltd., Suwon-si (KR)

(72) Inventors: Min Woo PARK, Suwon-si (KR); Seung Pil JUNG, Suwon-si (KR)

(73) Assignee: SAMSUNG ELECTRO-MECHANICS CO., LTD., Suwon-si (KR)

(21) Appl. No.: 14/923,992

(22) Filed: Oct. 27, 2015

(30) Foreign Application Priority Data
Nov. 19, 2014 (KR) 10-2014-0161682

(51) Int. Cl. H05K 1/18; H05K 3/30; H05K 1/11

(52) U.S. Cl. CPC H05K 1/181; H05K 1/111; H05K 1/115; H05K 3/303; H05K 2201/10977

(57) ABSTRACT

The electronic device module and method thereof includes a board, an electronic device, a sealing part, and a connection conductor. The board includes external connection electrodes. The electronic device is mounted on the board. The sealing part is configured to seal the electronic device. The connection conductor is configured to penetrate through the sealing part and including one end bonded to the external connection electrodes of the board. One of the external connection electrodes includes a reinforcing via disposed in the board.

### CROSS-REFERENCE TO RELATED APPLICATION

This application claims the priority and benefit under 35 USC 119(a) of Korean Patent Application No. 10-2014-0161682 filed on Nov. 19, 2014, with the Korean Intellectual Property Office, the disclosure of which is incorporated herein by reference.

### BACKGROUND

1. Field

The following description relates to an electronic device module having an external terminal disposed on an outer surface of a sealing part, and a method of manufacturing the same.

2. Description of Related Art

In order for electronic devices to be miniaturized and lightened, system-on-chip (SOC) technology, in which individual devices are provided on a single chip, system-in-package (SIP) technology, in which individual devices are integrated in a single package, and technology to decrease respective sizes of mounted components is needed.

To miniaturize electronic device modules while maintaining high levels of performance, a structure in which one or more electronic components are mounted on both surfaces of a board and a structure in which external terminals are formed on both surfaces of a package is further needed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided an electronic device module, including: a board including external connection electrodes; an electronic device mounted on the board; a sealing part configured to seal the electronic device; and a connection conductor configured to penetrate through the sealing part and including one end bonded to the external connection electrodes of the board, wherein one of the external connection electrodes includes a reinforcing via disposed in the board.

The external connection electrodes may include an electrode pad disposed on a surface of the board and bonded to one end of the reinforcing via.

Another end of the reinforcing via may be bonded to a circuit pattern provided in the board.

Another end of the reinforcing via may be bonded to a dummy pattern provided in the board.

Another end of the reinforcing via may be bonded to an insulating layer of the board.

The connection conductor may penetrate through the electrode pad to be directly bonded to the reinforcing via.

The sealing part may be formed of an epoxy molding compound (EMC).

The electronic device module may also include an external terminal bonded to another end of the connection conductor.

The dummy pattern may be a conductive pattern excluding an electrically connection to the circuit pattern to use the corresponding reinforcing via to complement an electrode pad formed on one end of the reinforcing via.

A horizontal cross-sectional area of the one end of the connection conductor may be adjacent to the board and is smaller than a cross-sectional area of another end of the connection conductor.

The other end of the connection conductor may be formed to be concave inwardly of a via hole.

The other end of the connection conductor may protrude to be convex outwardly of the board or to be flat in parallel with a surface of the board.

The reinforcing via may be externally exposed.

In accordance with an embodiment, there is provided a method to manufacture an electronic device module, including: preparing a board including external connection electrodes, wherein one of the external connection electrodes includes a reinforcing via disposed in the board; mounting an electronic device on a surface of the board; forming a sealing part sealing the electronic device; forming a via hole in the sealing part; and forming a connection conductor in the via hole.

The via hole may be formed using a laser.

The method may also include forming an external terminal on the connection conductor.

The external connection electrode of the board may include an electrode pad disposed on a surface of the board and bonded to one end of the reinforcing via.

Other features and aspects will be apparent from the following detailed description, the drawings, and the claims.

### BRIEF DESCRIPTION OF DRAWINGS

FIG. 1 is a cross-sectional view schematically illustrating an electronic device module, according to an embodiment;

FIG. 2 is a cross-section of an internal portion of the electronic device module illustrated in FIG. 1;

FIG. 3 is a partially enlarged cross-sectional view of part A of FIG. 1; and

FIGS. 4A through 4H are cross-sectional views illustrating a method of manufacturing the electronic device module illustrated in FIG. 1; and

FIG. 5 is a method illustrating the method of manufacturing the electronic device module in FIG. 1, according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

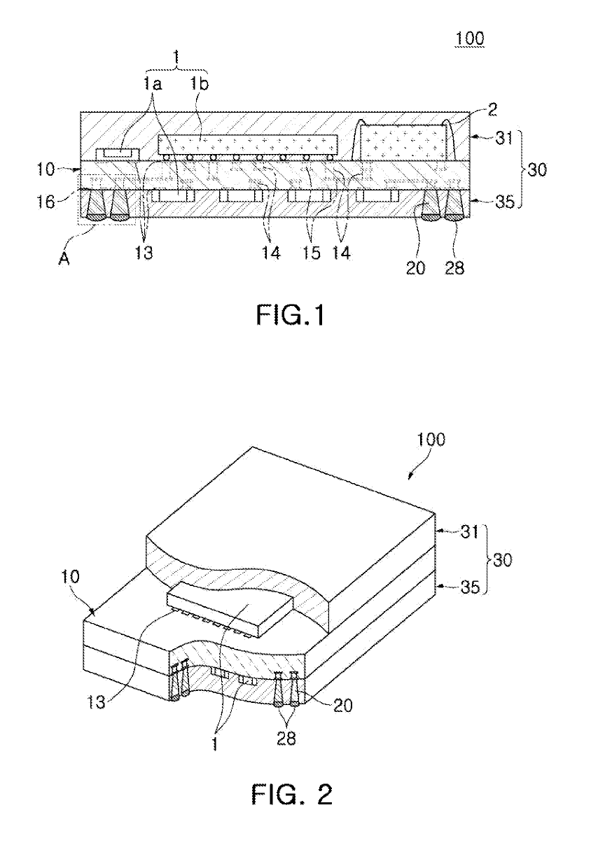

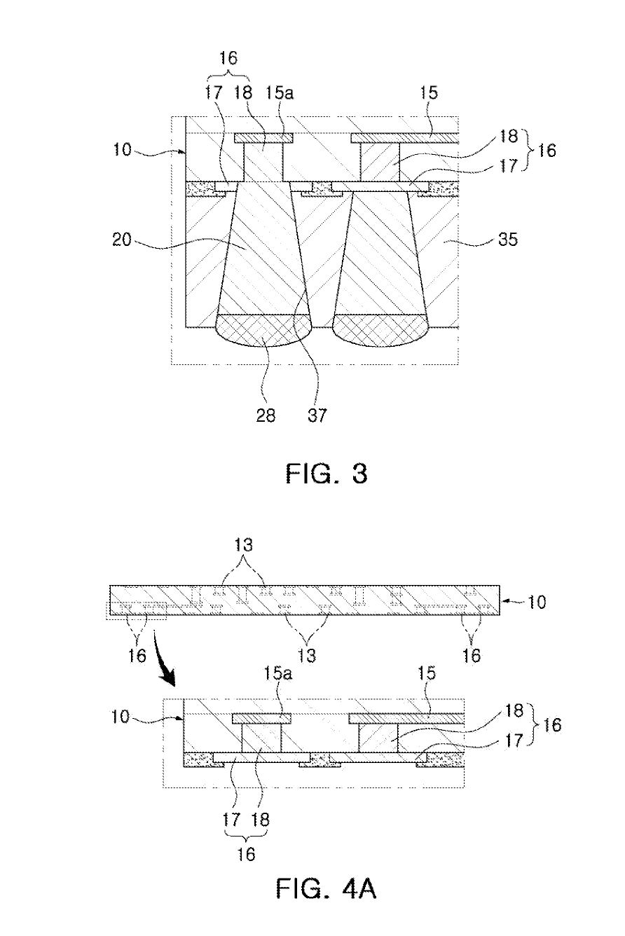

FIG. 1 is a cross-sectional view schematically illustrating an electronic device module, according to an embodiment. In addition, FIG. 2 is a cross-section of an internal portion of the electronic device module illustrated in FIG. 1, and FIG. 3 is a partially enlarged cross-sectional view of part A of FIG. 1.

Referring to FIGS. 1 through 3, an electronic device module 100, according to an embodiment, includes an electronic device 1, a board 10, a sealing part 30, a connection conductor 20, and an external terminal 28.

The electronic device 1 includes various structural devices such as a passive device 1a and an active device 1b. Persons of skill in the relevant art will appreciate that although FIG. 1 illustrates certain devices, other structural devices may be mounted on the electronic device 1 and/or the board 10 of the electronic device module 100. Furthermore, although a plurality of electronic devices 1 are illustrated in FIG. 1, a person of ordinary skill in the relevant art will appreciate that a single electronic device 1 may be configured in the electronic device module 100. The electronic device 1 may be mounted on an upper surface of the board 10 or a lower surface of the board 10. For illustrative examples, one of the electronic devices 1. Other electronic devices 1 illustrated in the electronic device module 100 may include similar configuration, each including at least one of a passive device 1a and an active device 1b.

The electronic devices 1 as described above may be mounted on one surface or both surfaces of the board 10. A case in which both the active device 1b and one passive device 1a of each of the electronic devices 1 are mounted on an upper surface of the board 10 and another passive device 1a is mounted on a lower surface thereof is illustrated in FIG. 1 by way of example. However, the number of active devices 1b and passive devices 1a and arrangement of electronic devices 1 are not limited thereto. Further, a number of electronic devices 1 may be disposed in various manners on both surfaces of the board 10 depending on sizes or shapes of the electronic devices 1 and the electronic device module 100.

In one illustrative example, electronic devices 1 are mounted on the board 10 through a flip chip method or are electrically bonded to the board 10 through a bonding wire 2.

Various kinds of board, for example, a ceramic board, a printed circuit board, or a flexible board may be used for the board 10. At least one electronic device 1 is mounted on at least one surface of the board 10.

Mounting electrodes 13 and external connection electrodes 16 are formed on one or both surfaces of the board 10. In one example, the electrodes 13 are configured to enable mounting of the electronic devices 1 and the external connection electrodes 16 are configured as external connection electrodes, which are electrically connected to the external terminal 28. One or more of the external connection electrodes 16 are electrically connected to a connection conductor 20 to be described below, and are connected to the external terminal 28 through the connection conductor 20.

In addition, although not illustrated, a wiring pattern electrically connecting the mounting electrodes 13 or the external connection electrodes 16 to each other is formed on both surfaces of the board 10.

The board 10, according to an embodiment, is a multilayer board including a plurality of layers, and circuit patterns 15 to form an electrical connection. The circuit patterns 15 are formed between each of the layers.

Further, the board 10, according to an embodiment, includes conductive vias 14 electrically connecting the mounting electrodes 13 and the external connection electrodes 16 and the circuit patterns 15 to each other.

In addition, the external connection electrodes 16, according to an embodiment, includes electrode pads 17 and reinforcing vias 18 (FIG. 3).

The electrode pad 17 is formed on one or both surfaces of the board 10 and is formed in a shape similar to that of the mounting electrode 13.

The reinforcing via 18 is a portion of the conductive vias 14. At least one end of the reinforcing via 18 is connected to the electrode pad 17. The reinforcing via 18 balances the rigidity of the electrode pad 17 formed on at least one end thereof. Further, the reinforcing via 18 is provided to allow removal or damage of a portion of the electrode pad 17, together with the sealing part 30, during formation of a via hole 37 in the sealing part 30 in a manufacturing process, to be described below.

As illustrated in FIG. 3, the circuit pattern 15 is connected to another end of the reinforcing via 18, opposite to the one end of the reinforcing via 18 connecting to the electrode pad 17.

In a case in which the circuit pattern 15 is connected to the other end of the reinforcing via 18, the reinforcing via 18 is used as an electric path. However, the reinforcing via 18 is not limited thereto, and may be connected to a dummy pattern 15a or formed to make direct contact with an insulating layer forming the board 10, instead of a conductive pattern, such as the circuit pattern 15.

In one example, the dummy pattern 15a is a conductive pattern that is not electrically connected to the circuit pattern 15, but is formed at the other end of the reinforcing via 18. Therefore, in a case in which the other end of the reinforcing via 18 is connected to the dummy pattern 15a or formed to make direct contact with the insulating layer, the corresponding reinforcing via 18 is not used as the electric path but used to complement the electrode pad 17 formed on one end thereof.

Although a case in which the reinforcing via 18 is provided in the external connection electrode 16 is described as an embodiment, the reinforcing via 18 is not limited thereto. For example, the reinforcing via 18 may be formed in all of the electrodes, for example, the mounting electrode, formed on the board 10.

Further, although in an example, the reinforcing via 18 penetrates through one layer of the board 10, which is formed multiple layers, a shape of the reinforcing via 18 is not limited to such configuration. For example, the reinforcing via 18 may penetrate through two or more layers of the board.

In addition, an electroplating wiring (not illustrated) may be formed on at least one surface of the board 10. The electroplating wiring is used in the formation of a connection conductor 20, to be described below, through electroplating.

The board 10, according to an embodiment, is a board having an array of a plurality of same mounting regions in order to simultaneously manufacture a plurality of individual modules. For instance, the board 10 is a board having a quadrangular shape having a wide area or a long strip shape. In this example, the electronic device module is manufactured in each of the mounting regions as individual modules.

The sealing part 30 (FIGS. 1 and 2) includes a first sealing part 31 formed on the upper surface of the board 10 and a second sealing part 35 formed on the lower surface of the board 10.

The sealing part 30 seals the electronic devices 1 mounted on both surfaces of the board 10. Further, the sealing part 30 is provided between the electronic devices 1 mounted on the board 10 to prevent short circuits from being generated between the electronic devices 1. The sealing part 30 also fixes the electronic devices 1 to the board while enclosing outer portions of the electronic devices 1 to safely protect the electronic devices 1 from external impact.

The sealing part 30, according to an embodiment, is formed of an insulating material containing a resin material, such as an epoxy molding compound (EMC). However, other insulating materials may be used to form the sealing part 30.

The first sealing part 31, according to an embodiment, is formed to entirely cover one surface of the board 10. Further, in one example, all of the electronic devices 1 are embedded in the first sealing part 31. In another example, some of the electronic devices are embedded in the first sealing part 31, allowing for other electronic devices to be external to the first sealing part 31 or to be exposed. For example, at least one of the electronic devices 1 embedded in the first sealing part 31 may be partially exposed to the outside of the first sealing part 31.

The second sealing part 35 is formed on the lower surface of the board 10, and the connection conductor 20 is formed in the second sealing part 35.

The second sealing part 35 is formed so that the electronic devices 1 are entirely embedded therein, similarly to the first sealing part 31. However, the second sealing part 35 may be formed so that the electronic devices 1 are at least partially externally exposed.

The connection conductor 20 is bonded to at least one surface of the board 10, and one end thereof is bonded to the board 10 and the other end thereof is exposed outside of the sealing part 30, such as the second sealing part 35. The connection conductor 20 is connected to the external terminal 28. Therefore, the connection conductor 20 is formed in the sealing part 30 to penetrate through the sealing part 30.

The connection conductor 20 is formed of a conductive material such as copper (Cu), gold (Au), silver (Ag), aluminum (Al), or an alloy.

In one embodiment, the connection conductor 20 is formed of the same material as that of the mounting electrode 13 and the external connection electrode 16. For example, in a case in which the external connection electrode 16 is formed of copper (Cu), the connection conductor 20 may also be formed of copper (Cu), such that the connection conductor 20 and the external connection electrode 16 are integrally formed of the same material. However, the material of the connection conductor 20 is not limited thereto. In an alternative embodiment, the mounting electrode 13 and the external connection electrode 16 are separately formed from the connection conduct 20 and formed of different materials.

The connection conductor 20, according to an embodiment, is formed so that a horizontal cross-sectional area of one end thereof adjacent to the board 10 is smaller than that of the other end thereof. For example, the connection conductor 20 is formed in a shape similar to a cone, with a horizontal cross-sectional area decreasing toward the board 10. However, the shape of the connection conductor 20 is not limited to a conical shape. The connection conductor 20 may be configured to have other shapes, such as a cylindrical shape having the same cross-sectional area.

The other end of the connection conductor 20 is formed to be concave inwardly of the via hole 37 as illustrated in FIG. 3. In addition, a portion of the external terminal 28 may be configured to be introduced into the via hole 37 to fill in the remaining space.

In this case, because the portion of the external terminal 28 is inserted into the via hole 37 in a protrusion shape, coupling strength with the connection conductor 20 or the sealing part 35 is increased.

In an alternative configuration, the other end of the connection conductor 20 protrudes to be convex outwardly of the board 10 or to be flat in parallel with one surface of the board 10.

The external terminal 28 is adhered, connected, or bonded to the other end of the connection conductor 20. The external terminal 28 may electrically and physically connect the electronic device module 100 and a main board (not illustrated) on which the electronic device module 100 is mounted. The external terminal 28 as described above may include a pad shape. However, the external terminal 28 is not limited thereto, and may be formed in various shapes, such as a bump shape or a solder ball shape.

A case in which the connection conductor 20 is formed only in the second sealing part 35 is described by way of example. However, the connection conductor 20 is not limited thereto, and may be formed in the first sealing part 31.

Next, a manufacturing method of an electronic device module, according to an embodiment, will be described.

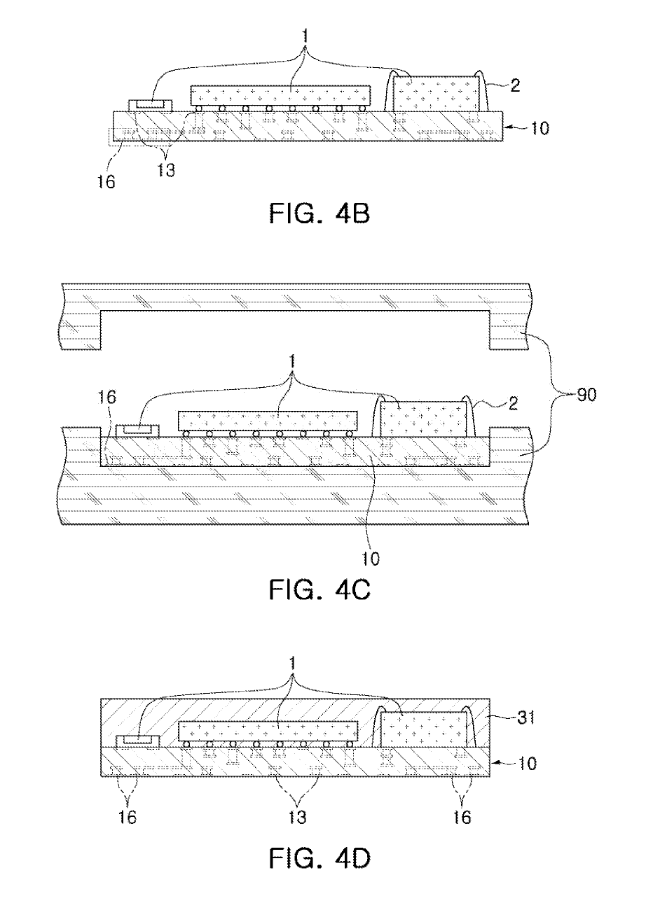

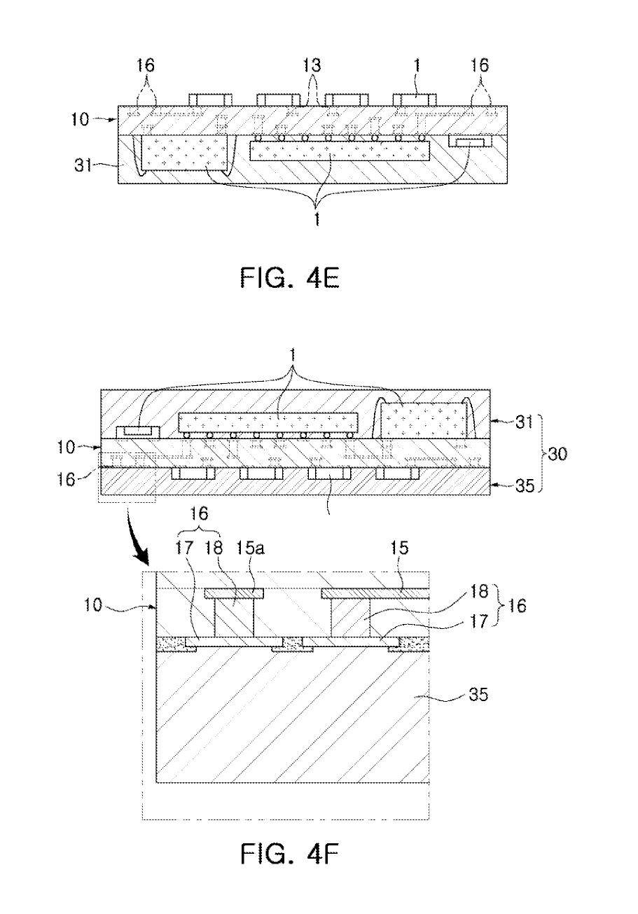

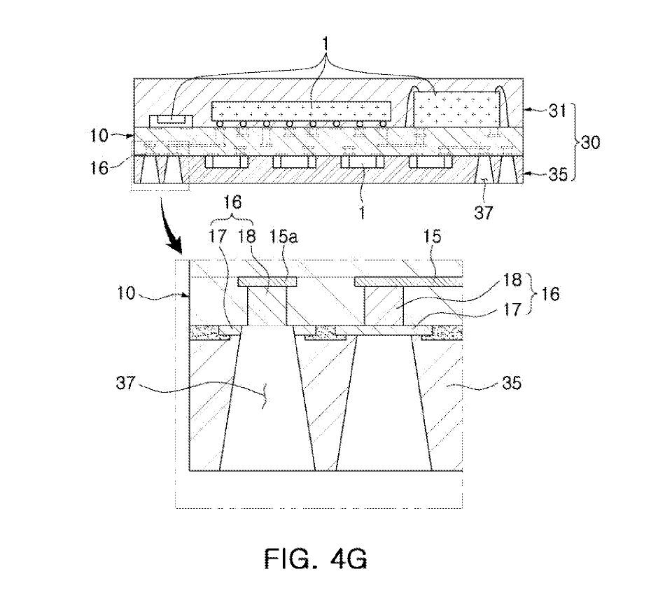

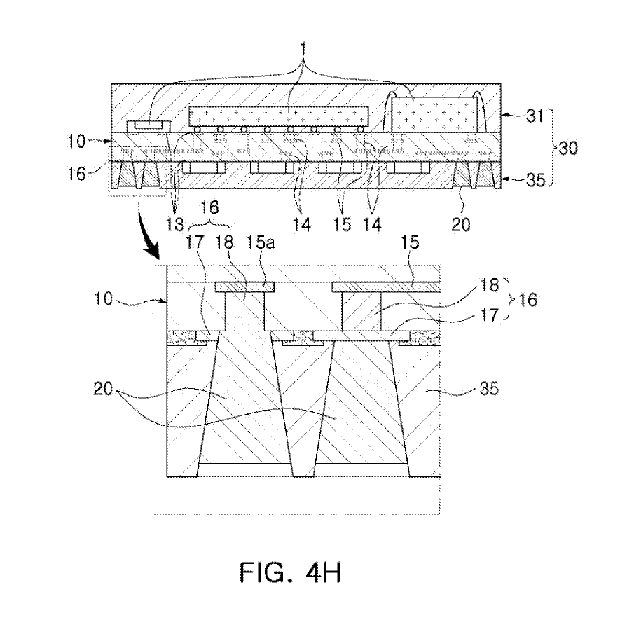

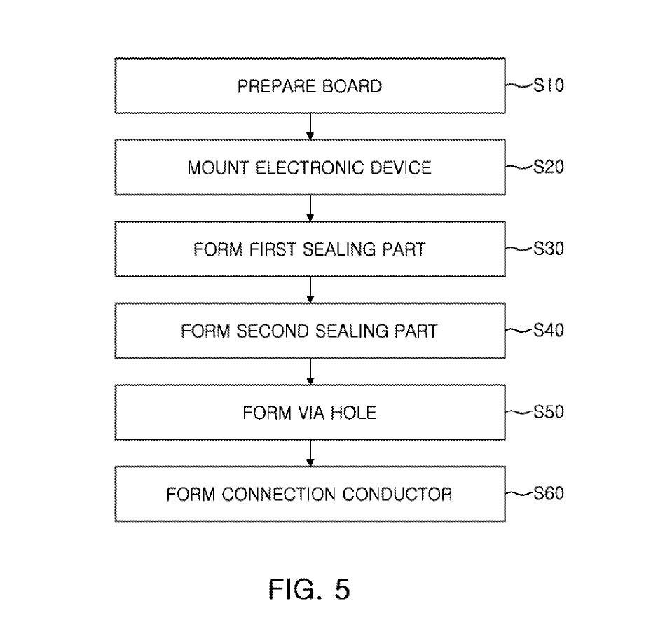

FIGS. 4A through 4H are cross-sectional views illustrating a manufacturing method of the electronic device module illustrated in FIG. 1. FIG. 5 illustrates the manufacturing method of the electronic device. For purposes of brevity, the functions performed in the manufacturing method are described in combination with the description of FIGS. 4A through 4H.

As illustrated in FIG. 4A, at operation 510 of FIG. 5, a board 10 is prepared. As described above, the board 10 is a multilayer board, and mounting electrodes 13 are formed on both surfaces of the board 10. In addition, external connection electrodes 16 are formed on a lower surface of the board 10.

Further, in the board 10, according to an embodiment, a reinforcing via 18 is formed in each of the external connection electrodes 16. One end of the reinforcing via 18 is bonded to the external connection electrode 16 in the board 10 as described above. The reinforcing via 18 is formed as a portion of a conductive via. Therefore, the reinforcing via 18 is collectively formed together with other conductive vias during a manufacturing process of the board.

Then, as illustrated in FIG. 4B, at operation 520 of FIG. 5, electronic devices 1 are mounted on one surface of the board 10, such as, an upper surface of the board 10. The mounting of the electronic devices 1 is performed by printing a solder paste on the mounting electrodes 13 formed on one surface of the board 10 using a screen printing method, seating the electronic devices 1 thereon, and applying heat to melt and cure the solder paste through reflow.

In an alternative embodiment, the mounting of the electronic devices 1 is performed by electrically connecting the mounting electrodes 13 and other electrodes of the electronic devices 1 to each other using a bonding wire 2, after seating the electronic devices 1 on one surface of the board 10.

Thereafter, at operation 530 of FIG. 5, a first sealing part 31 is formed on one surface of the board 10. In the forming of the first sealing part 31, the board 10 on which the electronic devices 1 are mounted is disposed in a mold 90 as illustrated in FIG. 4C.

The first sealing part 31 is formed by injecting a molding resin in the mold 90 as illustrated in FIG. 4D. The electronic devices 1 mounted on one surface of the board 10, such as, the upper surface of the board 10, is protected by the first sealing part 31.

Furthermore, as illustrated in FIG. 4E, the electronic devices 1 are mounted on the lower surface of the board 10. The mounting of the electronic devices 1 is performed by printing a solder paste on the mounting electrodes 13, for instance, using a screen printing method, seating the electronic devices 1 thereon, and applying heat to melt and cure the solder paste through reflow.

As illustrated in FIG. 4F, at operation 540 of FIG. 5, a second sealing part 35 is formed on a lower portion of the board 10. The forming of the second sealing part 35 is performed by disposing the board 10 in the mold 90 and injecting the molding resin in the mold, similarly to the embodiment illustrated in FIG. 4C.

A connection conductor 20 is also formed. For instance, as illustrated in FIG. 4G, a via hole 37 is formed in the second sealing part 35. In one illustrative example, the via hole 37 is formed by laser drilling.

At operation 550 of FIG. 5, the via hole 37 is formed to have a conical shape of which a horizontal cross-sectional area is decreased toward the board 10.

Therefore, the external connection electrode 16 is externally exposed through the via hole as illustrated in FIG. 4G.

During the formation of the via hole 37, energy of a laser may be excessively applied due to deviation in the energy level of the laser, such that an electrode pad 17 of the external connection electrode 16 is partially or entirely removed as in the case of the enlarged left via hole 37 illustrated in FIG. 4G.

However, because the reinforcing via 18 is bonded to an inner surface of the electrode pad 17, even in the case that the electrode pad 17 is removed, the reinforcing via 18 is externally exposed through the via hole 37. Therefore, in this case, one end of the reinforcing via 18 can be used as the external connection electrode 16.

Therefore, acceptable tolerance with respect to a depth of the via hole 37 is increased to correspond to a thickness (or a height) of the reinforcing via 18 in the manufacturing method, according to an embodiment.

Accordingly, in some of the many advantages associated with the embodiments described, it is irrelevant whether the electrode pad 17 is damaged or removed by a laser during the formation of the via hole 37. Therefore, the formation of the via hole 37 is easily performed.

At operation 560 of FIG. 5, a conductive material is provided in the via hole 37 to form the connection conductor 20 as illustrated in FIG. 4H.

The connection conductor 20, according to an embodiment, is formed by a plating operation. In a case in which the connection conductor 20 is formed of a copper (Cu) material, copper plating may be performed.

In one example, the plating operation may be performed only through an electroplating method. In this case, the connection conductor 20 is formed while sequentially filling the via hole 37 from the external connection electrode 16 of the board 10, using an electroplating wiring (not illustrated) that is formed on the board 10. However, the connection conductor is not limited thereto, and an electroless plating method may be used.

Further, alternative processes may be used to form the connection conductor 20. For example, the connection conductor 20 is formed by applying a conductive paste using a screen printing method to complete the connection conductor 20, while filling in the via hole 37.

When the connection conductor 20 is formed by the above-mentioned process, as illustrated and described with respect to in FIG. 4A through 5, an external terminal 28 is formed on the other end of the connection conductor 20, thereby completing the electronic device module 100, according to an embodiment illustrated in FIG. 1.

In one illustrative example, the external terminal 28 is formed in various shapes such as a bump shape, a solder ball shape, or a pad shape.

In the electronic device module 100, according to an embodiment, the electronic devices 1 are mounted on both surfaces of the board 10, and all of the electronic devices 1 are sealed by the sealing part 30. Therefore, a significant number of devices may be mounted in a single electronic device module 100, which may be easily protected from external factors.

Further, because the external connection electrode 16 includes the reinforcing via 18, tolerance corresponding to the thickness (the height) of the reinforcing via 18 is secured during the formation of the via hole 37. Therefore, because precision of the formation of the via hole 37 is decreased, the electronic device module can be easily manufactured.

In addition, because the external connection electrode 16 is bonded to the connection conductor 20, through the reinforcing via 18, even in the case that the electrode pad 17 is removed during the manufacturing process, bonding reliability of the external connection electrode 16 and the connection conductor 20 is secured.

Furthermore, although a case in which the second sealing part 35 is formed after the first sealing part 31 is formed is described by way of example, a formation sequence of the first and second sealing parts 31 and 35, respectively, is not limited thereto. The formation sequence may vary. For example, the second sealing part 35 may be formed first, or the first and second sealing parts 31 and 35 may be simultaneously formed.

As set forth above, in the electronic device module, according to various embodiments, the electronic devices are mounted on both surfaces of the board, and all of the electronic devices are sealed by the sealing part. Therefore, a significant number of devices may be mounted in the single electronic device module, which are easily protected from external factors.

Further, because acceptable tolerance corresponding to the thickness of the reinforcing via is secured during the formation process of the via hole, precision of the formation of the via hole is decreased. Thus, the electronic device module is easily manufactured.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

While this disclosure includes specific examples, it will be apparent to a person skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. An electronic device module, comprising:
a board comprising external connection electrodes;
an electronic device mounted on the board;
a sealing part configured to seal the electronic device; and
a connection conductor configured to penetrate through the sealing part and comprising one end bonded to the external connection electrodes of the board,
wherein one of the external connection electrodes comprises a reinforcing via disposed in the board.

2. The electronic device module of claim 1, wherein the external connection electrodes comprises an electrode pad disposed on a surface of the board and bonded to one end of the reinforcing via.

3. The electronic device module of claim 2, wherein another end of the reinforcing via is bonded to a circuit pattern provided in the board.

4. The electronic device module of claim 2, wherein another end of the reinforcing via is bonded to a dummy pattern provided in the board.

5. The electronic device module of claim 2, wherein another end of the reinforcing via is bonded to an insulating layer of the board.

6. The electronic device module of claim 2, wherein the connection conductor penetrates through the electrode pad to be directly bonded to the reinforcing via.

7. The electronic device module of claim 1, wherein the sealing part is formed of an epoxy molding compound (EMC).

8. The electronic device module of claim 1, further comprising:
an external terminal bonded to another end of the connection conductor.

9. The electronic device module of claim 1, wherein the dummy pattern is a conductive pattern excluding an electrically connection to the circuit pattern to use the corresponding reinforcing via to complement an electrode pad formed on one end of the reinforcing via.

10. The electronic device module of claim 1, wherein a horizontal cross-sectional area of the one end of the connection conductor is adjacent to the board and is smaller than a cross-sectional area of another end of the connection conductor.

11. The electronic device module of claim 10, wherein the other end of the connection conductor is formed to be concave inwardly of a via hole.

12. The electronic device module of claim 10, wherein the other end of the connection conductor protrudes to be convex outwardly of the board or to be flat in parallel with a surface of the board.

13. The electronic device module of claim 1, wherein the reinforcing via is externally exposed.

14. A method to manufacture an electronic device module, comprising:
preparing a board comprising external connection electrodes, wherein one of the external connection electrodes comprises a reinforcing via disposed in the board;
mounting an electronic device on a surface of the board;
forming a sealing part sealing the electronic device;
forming a via hole in the sealing part; and
forming a connection conductor in the via hole.

15. The method of claim 14, wherein the via hole is formed using a laser.

16. The method of claim 14, further comprising:
forming an external terminal on the connection conductor.

17. The method of claim 14, wherein the external connection electrode of the board comprises an electrode pad disposed on a surface of the board and bonded to one end of the reinforcing via.
